(19) United States
(12) Patent Application Publication
(10) Pub. No.: US 2024/0294687 A1
(43) Pub. Date: Sep. 5, 2024

(54) RESIN COMPOSITION, METHOD OF MANUFACTURING DISPLAY DEVICE, AND DISPLAY DEVICE

(71) Applicant: Samsung Display Co., LTD., Yongin-si (KR)

(72) Inventor: Keisuke MORITA, Yokohama (JP)

(21) Appl. No.: 18/433,066

(22) Filed: Feb. 5, 2024

(30) Foreign Application Priority Data
Feb. 10, 2023 (KR) 10-2023-0018291

(51) Int. Cl. C08F 265/06; C08F 2/36; C08F 2/50; G06F 1/16; H10K 59/80; H10K 71/40; H10K 71/50

(52) U.S. Cl. CPC C08F 265/06; C08F 2/36; C08F 2/50; G06F 1/1637; H10K 59/8722; H10K 71/421; H10K 71/50

(57) ABSTRACT

A resin composition includes: a (meth)acrylate copolymer including a first structural unit, a second structural unit, and a third structural unit, which are represented by certain structures of Formulae, respectively; a urethane (meth)acrylate oligomer; a monofunctional (meth)acrylate monomer; and a photoinitiator. Provided is a display device including, between the window and the display module, an adhesive member including a polymer derived from the resin composition.

This application claims priority to Korean Patent Application No. 10-2023-0018291, filed on Feb. 10, 2023, and all the benefits accruing therefrom under 35 U.S.C. § 119, the content of which in its entirety is herein incorporated by reference.

### BACKGROUND

The present disclosure herein relates to a resin composition, a method of manufacturing a display device, the method including preparing an adhesive member, and a display device manufactured thereby.

Various display devices used in multimedia devices such as a television, a mobile phone, a tablet computer, a navigation device, and a game console are being developed. An adhesive resin used to an adhesive member applied to various types of display devices is desirable to have excellent coating properties on members of various types of display devices.

When an adhesive resin is cured in the atmosphere containing oxygen in order to form the adhesive member, a curing inhibition phenomenon occurs, and adhesiveness is not sufficient, so that a method to solve this is desirable.

### SUMMARY

The present disclosure provides a resin composition capable of exhibiting excellent adhesiveness when cured in the atmosphere containing oxygen, and a method of manufacturing a display device including an adhesive member formed by using the resin composition.

The present disclosure also provides a display device including an adhesive member having excellent adhesive reliability at room temperature and a high temperature.

An embodiment of the invention provides a resin composition including: a (meth)acrylate copolymer including a first structural unit represented by following Formula 1a, a second structural unit represented by following Formula 1b, and a third structural unit represented by following Formula 1c, a urethane (meth)acrylate oligomer, a monofunctional (meth)acrylate monomer, and a photoinitiator:

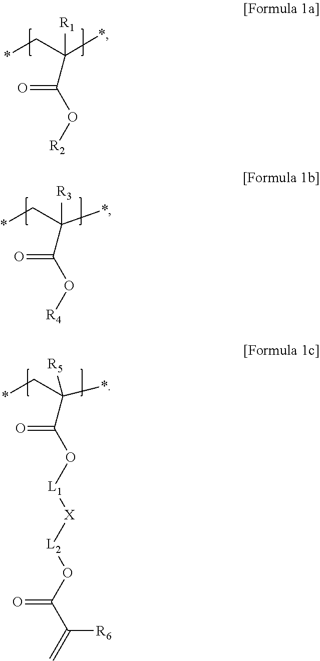

In Formula 1a to Formula 1c above, R₁, R₃, R₅, and R₆ are each independently a hydrogen atom or a methyl group, R₂ is a substituted or unsubstituted alkyl group having 1 to 18 carbon atoms or an oxy group, R₄ is a functional group having at least one substituted or unsubstituted aliphatic ring group, L₁ and L₂ are each independently a substituted or unsubstituted alkylene group having 1 to 18 carbon atoms or a substituted or unsubstituted alkyleneoxy group having 1 to 18 carbon atoms, and X is an ether group, an ester group, a urethane group, or an amide group.

In an embodiment, in the resin composition, the (meth)acrylate copolymer may have a weight-average molecular weight of about 1,000 grams per mol (g/mol) to about 50,000 g/mol.

In an embodiment, in the resin composition, with respect to 100 parts by weight of the urethane (meth)acrylate oligomer, the monofunctional (meth)acrylate monomer, and the photoinitiator, the (meth)acrylate copolymer may be included in an amount of about 0.1 parts by weight to about 50 parts by weight.

In an embodiment, in the resin composition, with respect to 100 mole percents (mol %) of the (meth)acrylate copolymer, a content of the third structural unit may be about 0.01 mol % to about 50 mol %.

In an embodiment, in the resin composition, the urethane (meth)acrylate oligomer may have a weight-average molecular weight of about 5,000 to about 100,000.

In an embodiment, the resin composition may have a peel strength of about 400 gf/25 mm or more at about 25° C. according to Japanese Industrial Standard (JIS K6854) after photo-cured. In an embodiment, the resin composition may also have a peel strength of about 100 gf/25 mm or more at about 60° C. according to JIS K6854 after photo-cured.

In an embodiment, the resin composition may not include an organic solvent.

In an embodiment, in the resin composition, the (meth)acrylate copolymer may be a random copolymer, and be represented by following Formula 1 below:

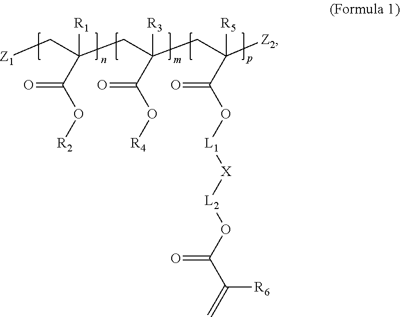

In Formula 1 above, Z₁ and Z₂ are each independently a functional group which does not have activity of radicals, cations, and anions, 0.01≤p/(n+m+p)≤50, and R₁ to R₆, L₁, L₂, and X are defined as Formula 1a to Formula 1c above.

In an embodiment of the invention, a method of manufacturing a display device includes providing the above-described resin composition of an embodiment on a first substrate, irradiating the resin composition with ultraviolet light in the atmosphere to form an adhesive member, and providing a second substrate on the adhesive member.

In an embodiment of the invention, a display device includes a display panel, a window disposed on the display panel, and an adhesive member disposed between the display panel and the window, where the adhesive member includes a polymer derived from the above-described resin composition of an embodiment.

### BRIEF DESCRIPTION OF THE FIGURES

The accompanying drawings are included to provide a further understanding of the invention, and are incorporated in and constitute a part of this specification. The drawings illustrate exemplary embodiments of the invention and, together with the description, serve to explain principles of the invention. In the drawings:

FIG. 1 is a perspective view illustrating a display device of an embodiment;

FIG. 2 is an exploded perspective view illustrating the display device of an embodiment;

FIG. 3 is a cross-sectional view illustrating a display device of an embodiment;

Each of FIGS. 4A to 4C is a view schematically illustrating an operation of manufacturing a display device of an embodiment;

FIG. 5 is a cross-sectional view illustrating a display device of an embodiment; and

FIG. 6 is a cross-sectional view illustrating a display device of an embodiment.

### DETAILED DESCRIPTION

The invention may be modified in various manners and have many forms, and thus specific embodiments will be exemplified in the drawings and described in detail in the detailed description. It should be understood, however, that it is not intended to limit the invention to the particular forms disclosed, but rather, is intended to cover all modifications, equivalents, and alternatives falling within the spirit and scope of the invention.

In the present specification, when a component (or a region, a layer, a portion, etc.) is referred to as being “on,” “connected to,” or “coupled to” another component, it means that the component may be directly disposed on/connected to/coupled to the other component, or that a third component may be disposed therebetween.

Like reference numerals refer to like components throughout. Also, in the drawings, the thicknesses, ratios, and dimensions of the components are exaggerated for effective description of technical contents. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” The term “and/or” includes all of one or more combinations that can be defined by associated items.

It will be understood that, although the terms “first,” “second,” etc. may be used herein to describe various components, these components should not be limited by these terms. These terms are only used to distinguish one component from another. For example, a first component could be termed a second component, and, similarly, a second component could be termed a first component, without departing from the scope of the invention. The terms of a singular form may include plural forms unless the context clearly indicates otherwise.

In addition, terms such as “below,” “under,” “on,” and “above” may be used to describe the relationship between components illustrated in the figures. The terms are used as a relative concept and are described with reference to the direction indicated in the drawings.

It should be understood that the terms “comprise,” or “have” are intended to specify the presence of stated features, integers, steps, operations, components, parts, or combinations thereof in the specification, but do not preclude the presence or addition of one or more other features, integers, steps, operations, components, parts, or combinations thereof.

Unless otherwise defined, all terms (including technical and scientific terms) used herein have the same meaning as commonly understood by one of ordinary skill in the art to which the invention belongs. In addition, it will be understood that terms, such as those defined in commonly used dictionaries, should be interpreted as having a meaning that is consistent with their meaning in the context of the relevant art and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

In the specification, the term “substituted or unsubstituted” may mean substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the invention is not limited thereto.

In the specification, a cycloalkyl group may mean a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but the embodiment of the invention is not limited thereto.

In the description, an alkenyl group means a hydrocarbon group including at least one carbon double bond in the middle or terminal of an alkyl group having 2 or more carbon atoms. The alkenyl group may be a linear chain or a branched chain. The carbon number is not specifically limited, but is 2 to 30, 2 to 20 or 2 to 10. Examples of the alkenyl group include a vinyl group, a 1-butenyl group, a 1-pentenyl group, a 1,3-butadienyl group, a styrenyl group, a styryl vinyl group, etc., but the embodiment of the invention is not limited thereto.

In the specification, an alkynyl group means a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, etc., but the embodiment of the invention is not limited thereto.

In the specification, the hydrocarbon ring group means any functional group or substituent derived from an aliphatic hydrocarbon ring. The hydrocarbon ring group may be a saturated hydrocarbon ring group having 5 to 20, or 5 to 10 ring-forming carbon atoms.

In the specification, an aryl group means any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the invention is not limited thereto.

The heterocyclic group herein means any functional group or substituent derived from a ring containing at least one of B, O, N, P, Si, S or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si, S or Se as a heteroatom. If the heterocyclic group contains two or more heteroatoms, the two or more heteroatoms may be the same as or different from each other. The heterocyclic group may be a monocyclic heterocyclic group or a polycyclic heterocyclic group and has the concept including a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, S or Se as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the embodiment of the invention is not limited thereto.

In the specification, the heteroaryl group may contain at least one of B, O, N, P, Si, S or Se as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the invention is not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a propyldimethylsilyl group, a triphenylsilyl group, a diphenylsilyl group, a phenylsilyl group, etc., but the embodiment of the invention is not limited thereto.

In the specification, the number of carbon atoms in the amino group is not specifically limited, but may be 1 to 30, 1 to 20, 1 to 10, or 1 to 6. The amino group may include an alkyl amino group, an aryl amino group, or a heteroaryl amino group. Examples of the amino group include a methylamino group, a dimethylamino group, a phenylamino group, a diphenylamino group, a naphthylamino group, a 9-methyl-anthracenylamino group, etc., but are not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the invention is not limited thereto.

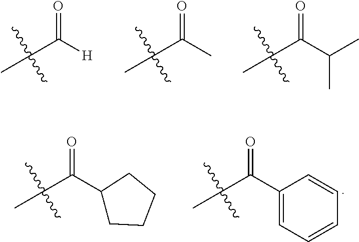

In the specification, the number of carbon atoms in the sulfinyl group and the sulfonyl group is not particularly limited, but may be 1 to 30, 1 to 20, 1 to 10, or 1 to 6. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may mean that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the invention is not limited thereto.

In the specification, an oxy group may mean that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20, 1 to 10, or 1 to 6. Examples of the oxy group may include methoxy, ethoxy, n-propoxy, isopropoxy, butoxy, pentyloxy, hexyloxy, octyloxy, nonyloxy, decyloxy, benzyloxy, etc., but the embodiment of the invention is not limited thereto.

The boron group herein may mean that a boron atom is bonded to the alkyl group or the aryl group as defined above. The boron group includes an alkyl boron group and an aryl boron group. Examples of the boron group may include a dimethylboron group, a trimethylboron group, a t-butyldimethylboron group, a diphenylboron group, a phenylboron group, etc., but the embodiment of the invention is not limited thereto.

In the specification, the number of carbon atoms in an amine group is not specifically limited, but may be 1 to 30, 1 to 20, 1 to 10, or 1 to 6. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, etc., but the embodiment of the invention is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described above.

In the specification, the aryl group among an aryloxy group, an arylthio group, an arylsulfoxy group, an arylamino group, an arylboron group, an arylsilyl group, an arylamine group is the same as the examples of the aryl group described above.

In the specification, the (meth)acrylate means acrylate and/or methacrylate.

In the specification, a functional group having at least one aliphatic ring group may mean a functional group including at least one hydrocarbon bonded in a ring. Specifically, in the functional group having at least one aliphatic ring group, the aliphatic ring group is one or more carbon rings without aromatic characteristics and may include a monocyclic ring or polycyclic ring.

“------*” herein means a position to be linked.

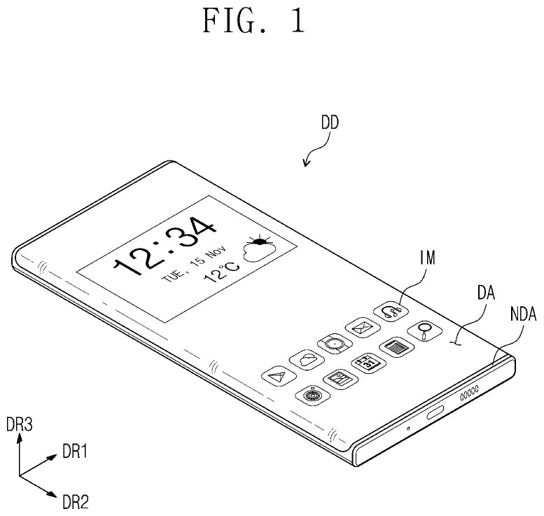

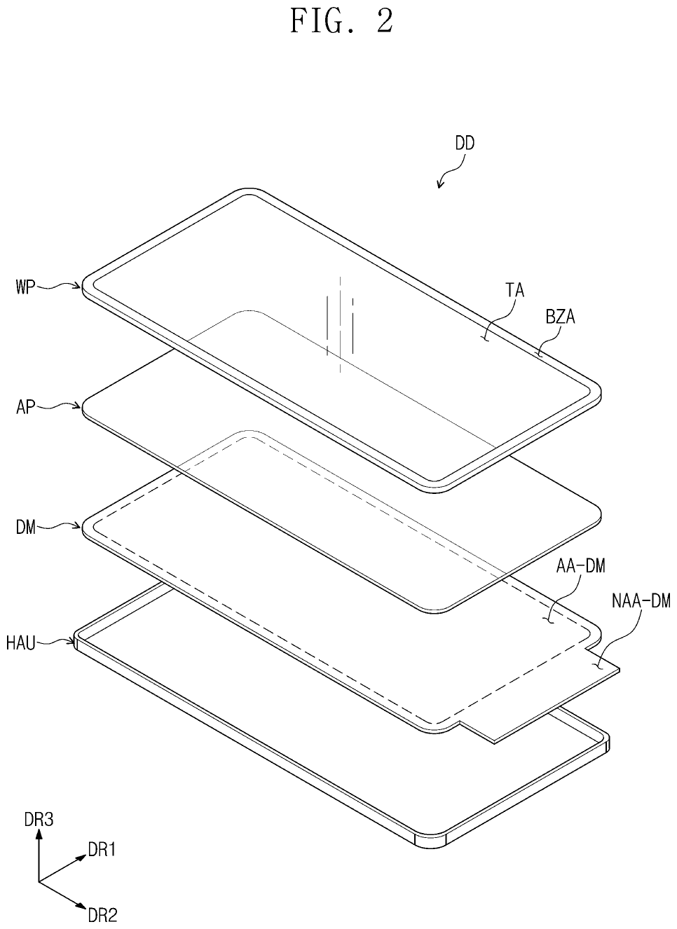

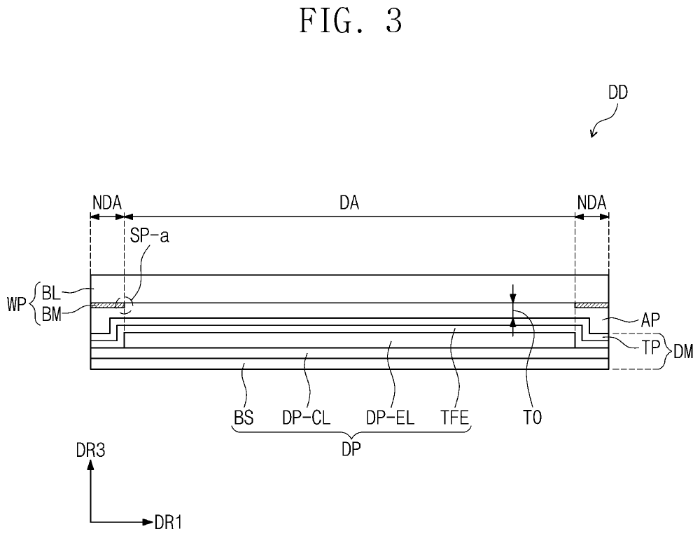

Hereinafter, an adhesive member of an embodiment of the invention and a display device including the same will be described with reference to the accompanying drawings. FIG. 1 is a perspective view illustrating a display device of an embodiment. FIG. 2 is an exploded perspective view of the display device according to an embodiment.

The display device DD of an embodiment illustrated in FIG. 1 may be activated by an electrical signal. For example, the display device DD may be a personal computer, a laptop computer, a personal digital terminal, a game console, a portable electronic device, a television, a monitor, an outdoor billboard, a car navigation device, or a wearable device, but the embodiment of the invention is not limited thereto. FIG. 1 exemplarily illustrates that the display device DD is a mobile phone.

Referring to FIG. 1, the display device DD according to an embodiment may display an image IM through a display region DA. The display region DA may include a plane defined by a first directional axis DR1 and a second directional axis DR2. The display device DD may display the image IM toward a third directional axis DR3 in a display region DA. The display region DA may include a curved surface bent from at least one side of a plane defined by the first directional axis DR1 and the second directional axis DR2. The display device DD of an embodiment illustrated in FIG. 1 is illustrated to include two curved surfaces bent from opposite side surfaces of the plane defined by the first directional axis DR1 and the second directional axis DR2, respectively. However, the shape of the display region DA is not limited thereto. For example, the display region DA may include only the plane defined by the first directional axis DR1 and the second directional axis DR2, and the display region DA may further include four curved surfaces bent from at least two sides, for example, four sides of the plane defined by the first directional axis DR1 and the second directional axis DR2, respectively.

The display device DD of an embodiment may be flexible. The term of “flexible” means a characteristic capable of being curved, and may include all structures from being fully bent to being bent in several nanometers scale. For example, the display device DD may be a foldable display device. Also, the display device DD may be rigid.

The non-display region NDA may be an area adjacent to the display region DA. The non-display region NDA may surround the display region DA. Thus, a shape of the display region DA may be substantially defined by the non-display region NDA. However, this is illustrated by way of example. For example, the non-display region NDA may be disposed adjacent to only one side of the display region DA or omitted. The display region DA may be provided in various shapes, and is not limited to any one embodiment.

FIG. 1 and the drawings below illustrate the first directional axis DR1 to third directional axis DR3, and the directions indicated by the first to third directional axes DR1, DR2 and DR3 described in this specification are relative concepts and may be converted into other directions. In addition, the directions indicated by the first to third directional axes DR1, DR2 and DR3 may be described as first to third directions, and the same reference symbols may be used. In this specification, the first direction axis DR1 and the second direction DR2 are orthogonal to each other, and the third direction axis DR3 may be a normal line direction with respect to the plane defined by the first direction DR1 and the second direction DR2.

The display device DD may have a thickness direction parallel to a third directional axis DR3 that is the normal direction with respect to a plane defined by the first directional axis DR1 and the second directional axis DR2. In this specification, a front surface (or a top surface, an upper surface, an upper portion) and a rear surface (or a bottom surface, a lower surface, a lower portion) of each member constituting the display device DD may be defined on the basis of the third directional axis DR3. In addition, in this specification, the direction in which the third directional axis DR3 is extended is parallel to a thickness direction, a front surface (or a top surface, an upper surface, an upper portion) means a surface (or direction) adjacent to the surface on which the image IM is displayed, and a rear surface (or a bottom surface, a lower surface, a lower portion) means a surface (or direction) spaced from the surface on which the image IM is displayed.

Referring to FIG. 2, the display device DD may include a display module DM, a window WP disposed on the display module DM, and an adhesive member AP disposed between the display module DM and the window WP. In addition, the display device DD may further include a housing HAU in which the display module DM is accommodated.

In the display device DD illustrated in FIGS. 1 and 2, the window WP and the housing HAU may be coupled to constitute the exterior of the display device DD. The housing HAU may be disposed on the lower portion of the display module DM. The housing HAU may include a material having a relatively higher rigidity. In an embodiment, for example, the housing HAU may include a plurality of frames and/or plates formed of glass, plastic, or metals. The housing HAU may provide a certain accommodating space. The display module DM may be accommodated in the accommodating space and be protected from an external impact.

The display module DM may be activated in response to an electrical signal. The display module DM may be activated to display the image IM (see FIG. 1) in the display region DA (see FIG. 1) of the display device DD. An active region AA-DM and a peripheral region NAA-DM may be defined in the display module DM. The active region AA-DM may be a region which is activated in response to an electrical signal. The peripheral region NAA-DM may be a region that is located to be adjacent to at least one side of the active region AA-DM. A circuit or a wiring for driving the active region AA-DM may be disposed in the peripheral region NAA-DM.

The adhesive member AP may be formed from a resin composition of an embodiment. The adhesive member AP may include the polymer derived from the resin composition of an embodiment. The resin composition of an embodiment will be described later. The display module DM and the window WP may be coupled by the adhesive member AP. The adhesive member AP may exhibit excellent adhesive characteristics at room temperature, about 25° C., and a high temperature of about 60° C.

The window WP may include a transmission region TA and a bezel region BZA. The front surface of the window WP including the transmission region TA and the bezel region BZA corresponds to the front surface of the display device DD. The transmission region TA may overlap at least a portion of the active region AA-DM of the display module DM. The transmission region TA may be an optically clear region. The image IM (see FIG. 1) may be provided to a user through the transmission region TA.

The bezel region BZA may have a light transmittance relatively lower than the transmission region TA. The bezel region BZA may define the shape of the transmission region TA. The bezel region BZA may be adjacent to the transmission region TA, and may surround the transmission region TA.

The bezel region BZA may have a certain color. The bezel region BZA may cover a peripheral region NAA-DM of the display module DM to prevent the peripheral region NAA-DM from being viewed from the outside. However, the embodiment of the invention is not limited to the configuration illustrated, the bezel region BZA may be disposed adjacent to only one side of the transmission region TA, and at least a part thereof may be omitted.

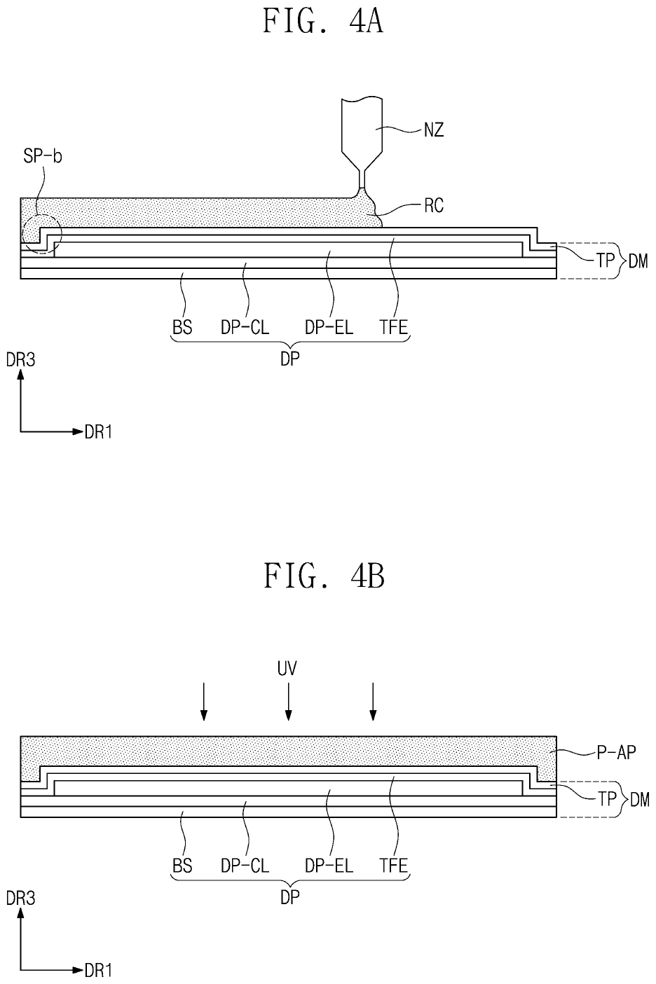

FIG. 3 is a cross-sectional view illustrating a display device DD according to an embodiment. In FIG. 3, the housing HAU in FIG. 2 is omitted, and a display module DM, an adhesive member AP, and a window WP are illustrated.

Referring to FIG. 3, the display module DM may include a display panel DP and an input sensing unit TP disposed on the display panel DP. The display panel DP may include a base substrate BS, a circuit layer DP-CL disposed on the base substrate BS, a display element layer DP-EL disposed on the circuit layer DP-CL, and an encapsulation layer TFE covering the display element layer DP-EL. The display device DD of an embodiment may include an adhesive member AP disposed between the display panel DP and the window WP. In an embodiment, for example, in the display device DD of an embodiment, the adhesive member AP may be disposed between the input sensing unit TP and the window WP. The adhesive member AP may be an optically clear adhesive resin layer (“OCR”).

The configuration of the display panel DP illustrated in FIG. 3, etc. is exemplary, and the configuration of the display panel DP is not limited thereto. In an embodiment, for example, the display panel DP may include a liquid crystal display element, and in this case, the encapsulation layer TFE may be omitted.

The base substrate BS may provide a base surface on which the circuit layer DP-CL is disposed. The base substrate BS may be a flexible substrate which is bendable, foldable, or rollable. The base substrate BS may be a glass substrate, a metal substrate, or a polymer substrate. However, the embodiment is not limited thereto, and the base substrate BS may be an inorganic layer, an organic layer, or a composite material layer in another embodiment.

The circuit layer DP-CL may include an insulation layer, a semiconductor pattern, a conductive pattern, a signal line, etc. In an embodiment, for example, the circuit layer DP-CL may include a switching transistor and a driving transistor for driving the light emitting element (not shown) of the display element layer DP-EL.

The display element layer DP-EL may include the light emitting element (not shown) which emits light. In an embodiment, for example, the light emitting element (not shown) may include an organic light emitting material, an inorganic light emitting material, an organic-inorganic light emitting material, quantum dots, quantum rods, a micro LED, or a nano LED.

The encapsulation layer TFE may be disposed on the upper portion of the display element layer DP-EL. The encapsulation layer TFE may protect the display element layer DP-EL from foreign substances such as moisture, oxygen, and/or the dust particles. The encapsulation layer TFE may include at least one inorganic layer. In addition, the encapsulation layer TFE may include at least one organic layer and at least one inorganic layer. In an embodiment, for example, the encapsulation layer TFE may include an inorganic layer, an organic layer, and an inorganic layer, which are sequentially stacked.

The input sensing unit TP may be disposed on the display panel DP. In an embodiment, for example, the input sensing unit TP may be directly disposed on the encapsulation layer TFE of the display panel DP. The input sensing unit TP may detect an external input, convert the external input to a predetermined input signal, and provide the input signal for the display panel DP. In an embodiment, for example, in the display device DD of an embodiment, the input sensing unit TP may be a touch sensing unit that senses a touch. The input sensing unit TP may recognize a user's direct touch, a user's indirect touch, a direct touch of an object, or an indirect touch of an object.

The input sensing unit TP may sense at least one of a location or force (pressure) of the externally applied touch. The input sensing unit TP may have various structures or may be formed of various materials, and is not limited to any one embodiment. The input sensing unit TP may include a plurality of sensing electrodes (not shown) so as to sense an external input. The sensing electrodes (not shown) may sense the external input in a capacitive manner. The display panel DP may receive an input signal from the input sensing unit TP, and generate an image corresponding to the input signal.

The window WP may protect the display panel DP, the input sensing unit TP, and the like. The image IM (see FIG. 1) generated in the display panel DP may be transmitted through the window WP to be provided to a user. The window WP may provide a touch surface of the display device DD.

The window WP may include a base layer BL and a printing layer BM. Although not illustrated, the window WP may further include at least one functional layer (not shown) provided on the base layer BL. In an embodiment, for example, the functional layer (not shown) may be a hard coating layer, an anti-fingerprint coating layer, or the like, but the embodiment of the invention is not limited thereto.

The base layer BL may be a glass substrate or plastic substrate. In an embodiment, for example, a tempered glass substrate may be used as the base layer BL in the window WP of an embodiment. Alternatively, the base layer BL may be formed of a flexible polymer resin. In an embodiment, for example, the base layer BL may be formed of polyimide, polyacrylate, polymethylmethacrylate, polycarbonate, polyethylene naphthalate, polyvinylidene chloride, polyvinylidene difluoride, polystyrene, ethylene-vinyl alcohol copolymer, or a combination thereof.

The printing layer BM may be disposed on one surface of the base layer BL. The printing layer BM may be provided on the bottom surface of the base layer BL adjacent to the display module DM. The printing layer BM may be disposed on an edge area of the base layer BL. The printing layer BM may be an ink printing layer. In addition, the printing layer BM may be a layer including a pigment or a dye. In the window WP, the bezel region BZA may be a portion in which the printing layer BM is provided.

The adhesive member AP may be disposed under the window WP. In the window WP, a step SP-a may be present between the printing layer BM and the base layer BL on which the printing layer BM is not provided. The adhesive member AP, which is formed from the resin composition according to an embodiment, has good flexibility and high adhesive strength, and thus may adhere to the window WP at the step SP-a without delamination.

The resin composition of an embodiment may include a (meth)acrylate copolymer, a urethane (meth)acrylate oligomer, a monofunctional (meth)acrylate monomer, and a photoinitiator.

The (meth)acrylate copolymer may include a first structural unit, a second structural unit, and a third structural unit. The first structural unit may be represented by following Formula 1a below, the second structural unit may be represented by following Formula 1b below, and the third structural unit may be represented by following Formula 1c below:

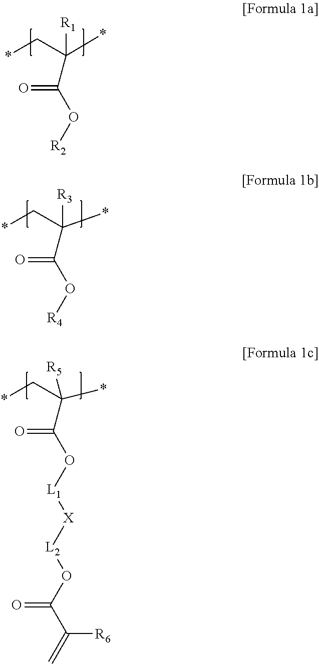

In Formula 1a, Formula 1b, and Formula 1c, R₁, R₃, R₅, and R₆ may be each independently a hydrogen atom or a methyl group. In an embodiment, for example, R₁, R₃, R₅, and R₆ may be all hydrogen atoms. Alternatively, at least one of R₁, R₃, R₅, or R₆ may be a methyl group. When each of R₁, R₃, R₅, and R₆ is a methyl group, the methyl group may be unsubstituted.
In Formula 1a, R₂ may be a substituted or unsubstituted alkyl group having 1 to 18 carbon atoms, or an oxy group. In an embodiment, for example, R₂ may be an unsubstituted methyl group.
In Formula 1b, R₄ may be a functional group having at least one substituted or unsubstituted aliphatic ring group. In an embodiment, R₄ may be a functional group including at least one substituted or unsubstituted cycloalkyl group. The substituted or unsubstituted cycloalkyl group may include a monocycle or polycycle having 3 to 20 carbon atoms. In addition, the substituted or unsubstituted cycloalkyl group may not have an unsaturated bond.
In Formula 1c, L₁ and L₂ may be each independently a substituted or unsubstituted alkylene group having 1 to 18 carbon atoms, or a substituted or unsubstituted alkyleneoxy group having 1 to 18 carbon atoms. The alkyleneoxy group is a functional group in which an alkylene group having 1 to 18 carbon atoms is bonded with an ether group, and for example, may be represented by —RO—. Here, R is an alkylene group having 1 to 18 carbon atoms, and O is an oxygen atom.
In Formula 1c, X may be an ether group (—O—), an ester group (—C(═O)O— or —O(C═O)—), a urethane group (—NHC(═O)O—), or an amide group. In the amide group, the nitrogen atom of the amide group may be substituted with a hydrogen atom, an alkyl group having 1 to 30 carbon atoms, a cycloalkyl group having 3 to 30 carbon atoms, or a substituted or unsubstituted aryl group having 6 to 30 carbon atoms.

In an embodiment, the third structural unit may be contained in an amount of about 0.01 mol % to about 50 mol % with respect to 100 mol % of the (meth)acrylate copolymer. The resin composition of an embodiment may suppress the deterioration of the surface curing due to oxygen during photo-curing in the atmosphere when the third structural unit is contained in the (meth)acrylate copolymer within the above content range, and may exhibit excellent tackiness and adhesiveness at room temperature and a high temperature.

In an embodiment, for example, the (meth)acrylate copolymer including the first structural unit represented by Formula 1a above, the second structural unit represented by Formula 1b above, and the third structural unit represented by Formula 1c above may be represented by Formula 1 below. The (meth)acrylate copolymer represented by Formula 1 below may be a random copolymer.

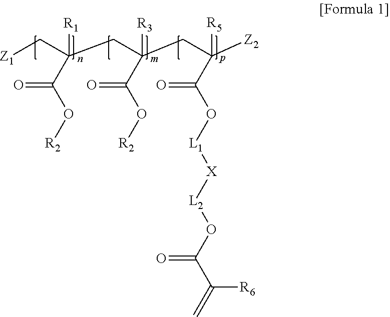

In Formula 1, Z₁ and Z₂ may be each independently a functional group which does not have activity of radicals, cations, and anions. Z₁ and Z₂ may be each independently a functional group bonded to an azo-based compound, a peroxide-based compound, or the like which is a cleaving group that is a radical initiator, or a functional group in which the compound is further modified through post-reaction. In an embodiment, for example, Z₁ and Z₂ may be each independently a methyl tert-butylate group (—C(CH₃)₂COOCH₃) included in V-601 that is an azo-based initiator. Alternatively, Z₁ and Z₂ may be each independently a 2,4,4-trimethylpentane group (—C(CH₃)₂CH₂C(CH₃)₃) included in VR-110 that is an azo-based initiator, or a laurylate group (—OOC(CH₂)₁₁CH₃) included in PEROYL L that is a peroxide-based initiator. However, the embodiment of the invention is not limited thereto.

In Formula 1, n+m+p=100 may be satisfied. In an embodiment, for example, n≠0 and m≠0 may be satisfied, and 0.01≤p/(n+m+p)≤50 may be satisfied.
In Formula 1, the same as described in Formula 1a to Formula 1c above may be applied with regard to R₁ to R₆, L₁, L₂, and X.

In an embodiment, the glass transition temperature (Tg) of the (meth)acrylate copolymer may be about 100° C. or higher. Accordingly, a cured product formed of the resin composition of an embodiment and the adhesive member AP may have improved adhesiveness.

The resin composition of an embodiment of the present invention may suppress the deterioration of curing on the surface of the resin composition applied on the substrate even when photo-curing is performed in the presence of oxygen due to including the above-described (meth)acrylate copolymer, thereby exhibiting excellent tackiness/adhesiveness. In addition, the resin composition of an embodiment may exhibit excellent tackiness/adhesiveness not only at room temperature but also at a high temperature during photo-curing.

The (meth)acrylate copolymer may have a weight-average molecular weight (Mw) of about 1,000 to about 50,000. When the weight-average molecular weight of the (meth)acrylate copolymer has the above-described range, the resin composition of the embodiment including the (meth)acrylate copolymer may exhibit excellent adhesiveness at room temperature and a high temperature during curing.

The resin composition of an embodiment may include about 0.1 parts by weight to about 50 parts by weight of the (meth)acrylate copolymer with respect to 100 parts by weight of a urethane (meth)acrylate oligomer, a monofunctional (meth)acrylate monomer, and a photoinitiator which will be described later. The resin composition of an embodiment may include the (meth)acrylate copolymer in the above-described content range to exhibit excellent peel strength characteristics after the curing of the resin composition.

The resin composition of an embodiment may include a urethane (meth)acrylate oligomer. The resin composition may include one or two or more urethane (meth)acrylate oligomers.

The urethane (meth)acrylate oligomer may include a photocurable compound including at least one (meth)acryloyl group having a urethane bond. The urethane (meth)acrylate oligomer may include at least one of an acrylate having a urethane bond, a urethane acrylate having a polycarbonate backbone, a urethane acrylate having a polyester backbone, or a urethane acrylate having a polyether backbone.

In an embodiment, the urethane (meth)acrylate oligomer may have a weight-average molecular weight (Mw) of about 5,000 to about 100,000. The urethane (meth)acrylate oligomer having a weight-average molecular weight within the above-described range is included in the resin composition in an oligomer state having a relatively high degree of polymerization, and thus it is possible to maintain a high degree of polymerization even after photo-curing. Accordingly, the adhesive member AP formed from the resin composition of an embodiment may exhibit excellent adhesion.

In an embodiment, for example, the resin composition of an embodiment may include, as a urethane (meth)acrylate oligomer, at least one of UF—C051 (manufactured by Kyoeisha Chemical Co., Ltd.) and UN-6304 (manufactured by Negami Chemical Industrial Co., Ltd.). However, this is exemplary, and the embodiment of the invention is not limited thereto.

In an embodiment, the resin composition including the urethane (meth)acrylate oligomer may exhibit low viscosity characteristics which allows to be applied by means of a method, such as a bar-coating method, an inkjet printing method, or a dispensing coating method. Accordingly, the resin composition of an embodiment may be applied on the substrate in a uniform amount and a uniform thickness, and the adhesive member AP formed from the resin composition may exhibit excellent adhesive reliability.

The resin composition of an embodiment may include a monofunctional (meth)acrylate monomer. The monofunctional (meth)acrylate monomer may include a plurality of different monomers. In an embodiment, for example, in the resin composition of an embodiment, the monofunctional (meth)acrylate monomer may include at least one monofunctional acrylate monomer and at least one monofunctional methacrylate monomer.

The monofunctional (meth)acrylate monomer may include at least one of 2-ethylhexyl acrylate, 4-hydroxy butyl acrylate, isodecyl acrylate, 2-methyl-2-ethyl-1,3-dioxolane-4-ylmethyl acrylate, or butyl acrylate.

The resin composition of an embodiment is a photocurable resin composition, and may include a photoinitiator. Any photoinitiator may be used without particular limitation as long as it can induce a polymerization reaction of a radical polymerizable compound during a curing process by means of ultraviolet light irradiation The photoinitiator may be a photoradical polymerization initiator. In an embodiment, for example, a photoradical polymerization initiator such as benzoin-based, hydroxy ketone-based, aminoketone-based, or phosphine oxide-based may be used as the photoinitiator.

In an embodiment, for example, the photoinitiator may include at least one of 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one.

In addition, the photoinitiator may include at least one of 2-methyl-1[4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, phenylbis(2,4,6-trimethylbenzoyl)phosphine oxide, [1-(4-phenylsulfanylbenzoyl)heptylideneamino]benzoate, [1-[9-ethyl-6-(2-methylbenzoyl)carbazol-3-yl]ethylideneamino] acetate, or bis(2,4-cyclopentadienyl)bis[2,6-difluoro-3-(1-pyrryl)phenyl] titanium(IV). In addition, the resin composition RC may include, as a photoinitiator, at least one of Omnirad 819 (IGM Resins, Inc.), or Omnirad 184 (IGM Resins, Inc.). Omnirad 819 (IGM Resins, Inc.) and Omnirad 184 (IGM Resins, Inc.) are radical polymerization initiators.

The resin composition of an embodiment may not substantially include an organic solvent. That is, the resin composition of an embodiment may be a solvent-free type. In an embodiment, when a solvent-free type resin composition is used to form the adhesive member AP, a process for drying an organic solvent may be omitted, thereby effectively improving production efficiency.

The adhesive member AP included in the display device of an embodiment may be formed by providing the resin composition on one surface of the window WP or the display module DM and then irradiating, with ultraviolet light, the resin composition provided on one surface of the window WP or the display module DM in the atmosphere and curing. However, the embodiment of the invention is not limited thereto. In an embodiment, for example, the adhesive member AP may be provided in a method in which the adhesive member AP is formed by curing the resin composition of an embodiment with ultraviolet light in a separate process, one surface of the adhesive member AP cured in the form of an adhesive film is laminated on one surface of the window WP or the display module DM, and one unattached surface of the window WP or the display module DM is attached on the other surface of the adhesive member AP.

In an embodiment, the thickness T0 of the adhesive member AP may be about 50 micrometers (m) to about 200 km. In an embodiment, for example, the adhesive member AP may have a thickness T0 of about 50 μm to about 100 μm. However, this is exemplary, and the thickness T0 of the adhesive member AP is not limited thereto.

In an embodiment, the adhesive member AP may have a peel strength (180° peel strength) in a 180° direction of about 400 gf/25 mm or more, or about 100 gf/25 mm or more. In an embodiment, for example, the adhesive member AP may have a 180° peel strength of about 400 gf/25 mm or more at about 25° C. In addition, the adhesive member AP may have a 180° peel strength of about 100 gf/25 mm or more at about 60° C.

In the present specification, the peel strength of the adhesive member AP is a value measured for a cured product formed of the resin composition of an embodiment. In an embodiment, for example, the peel strength of the adhesive member AP may be measured by using a specimen for measuring a peel strength, the specimen being prepared by applying the resin composition of an embodiment on a glass substrate (e.g., soda lime glass) and photo-curing to form a cured product, and laminating a polyethylene terephthalate (“PET”) film on the cured product. Here, the cured product may correspond to the adhesive member AP of an embodiment. The peel strength of the adhesive member AP is a value measured when the adhesive layer and the polyethylene terephthalate film are peeled off from the glass substrate at a peel temperature of room temperature and a high temperature and a peel angle of 1800 according to Japanese Industrial Standard (“JIS”) K6854. In the present specification, the room temperature may be a temperature of about 25° C., and the high temperature may be a temperature of about 60° C.

The adhesive member AP of an embodiment may have a 180° peel strength of about 400 gf/25 mm or more at room temperature and a 180° peel strength of about 100 gf/25 mm or more at a high temperature, thereby exhibiting excellent adhesive reliability. Accordingly, the display device DD including the adhesive member AP of an embodiment may exhibit excellent reliability because a delamination phenomenon does not occur at the interface of the adhesive member AP.

The display device DD of an embodiment may be formed by a method of manufacturing a display device of an embodiment. In the method of manufacturing a display device of an embodiment, the adhesive member AP may be formed from the resin composition of an embodiment described above. The method of manufacturing a display device of an embodiment may include providing a resin composition on a first substrate, forming an adhesive member AP by curing the resin composition, and disposing a second substrate on the adhesive member AP. In an embodiment, one of the first substrate or the second substrate may be the display module DM (see FIG. 3), and the rest other than the display module DM (see FIG. 3) may be the window WP (see FIG. 3).

FIGS. 4A to 4C schematically illustrate some operations of the method of manufacturing a display device according to an embodiment of the invention. FIG. 4A illustrates providing a resin composition for forming the adhesive member on the first substrate. FIG. 4B illustrates irradiating, with ultraviolet light, a preliminary adhesive member formed from the resin composition, and FIG. 4C illustrates disposing the second substrate on the adhesive member formed from the resin composition. Hereinafter, in describing the method of manufacturing a display device of an embodiment with reference to FIGS. 4A to 4C, the duplicated features which have been described with reference to FIGS. 1 to 3 are not described again, but their differences will be mainly described.

A first substrate is a member on which a resin composition RC is provided, and FIG. 4A illustrates that the resin composition RC is provided on one surface of the display module DM. The providing of the resin composition RC may include forming a preliminary adhesive member P-AP from the resin composition RC provided on one surface of the display module DM to laminate the preliminary adhesive member P-AP on the display module DM. In this case, the second substrate may be the window WP.

Unlike the configuration illustrated in FIG. 4A, the resin composition RC may be provided on one surface of the window WP. The preliminary adhesive member P-AP may be formed from the resin composition RC provided on one surface of the window WP. In this case, the second substrate may be the display module DM.

In some embodiments, the resin composition RC may be provided on a separate substrate (e.g., a carrier substrate). When the resin composition RC is provided on a separate substrate to form the preliminary adhesive member P-AP, the separate substrate may be subjected to a release treatment on the surface to which the resin composition RC is applied.

The resin composition RC may be provided by a method such as a bar-coating method, an inkjet printing method, or a dispensing method. The resin composition RC of an embodiment may have a viscosity value at about 25° C. of about 1.0 millipascal seconds (mPa·s) to about 50 mPa·s, and thus, may be easily discharged from the nozzle NZ and the like, and may be provided to maintain a thin and constant coating thickness. In addition, the resin composition has a viscosity value of about 1.0 mPa·s to about 50 mPa·s, and thus may be provided to cover the curvature of the stepped portion SP-b of the display module DM. That is, since the resin composition has a low viscosity value of about 50 mPa·s or less, the resin composition RC may be filled without an empty space in a curved portion such as the stepped portion SP-b. In addition, the resin composition RC provided through the nozzle NZ may have a viscosity value of about 1.0 mPa·s or more, so that the resin composition RC may be uniformly coated to a predetermined thickness without flowing out of the display module DM. The resin composition RC uniformly coated on the display module DM may form the preliminary adhesive member P-AP (see FIG. 4B).

The method of manufacturing a display device of an embodiment may not include the drying of the resin composition RC. The resin composition RC of an embodiment may be a solvent-free type resin composition that does not substantially include an organic solvent, and thus, after being applied onto the first substrate, a drying process may not be required. Accordingly, the method of manufacturing a display device of an embodiment may exhibit excellent manufacture efficiency.

Referring to FIGS. 4A and 4B, the preliminary adhesive member P-AP formed by coating the resin composition RC with a uniform thickness may be cured by light. In an embodiment, for example, the ultraviolet light UV may be provided to the preliminary adhesive member P-AP before the window WP is disposed on the preliminary adhesive member P-AP. When the ultraviolet light UV is provided to the preliminary adhesive member P-AP, the polymerization reaction may be performed in the resin composition RC forming the preliminary adhesive member P-AP. The preliminary adhesive member P-AP may be polymerized and then cured by the irradiated ultraviolet light UV to form a cured product. The cured product may correspond to the adhesive member AP of an embodiment.

In an embodiment, the curing of the preliminary adhesive member P-AP, that is, the resin composition RC, may be performed in the atmosphere. In the invention, the adhesive member AP (see FIG. 3) is formed from the resin composition RC of an embodiment, and thus even when oxygen is present in the atmosphere, the deterioration of the radical polymerization reaction on the surface of the resin composition RC applied on the first substrate is suppressed, thereby exhibiting excellent curing characteristics. In an embodiment, for example, since the (meth)acrylate copolymer included in the resin composition RC is segregated on the outermost surface side when the resin composition RC is cured, excellent adhesiveness of the adhesive member AP may be secured by a certain cohesive force.

Accordingly, in the method of manufacturing a display device of an embodiment, the resin composition RC may be completely cured by only irradiating the resin composition RC with ultraviolet light UV once, and thus the process steps may be reduced, and an increase in equipment for blocking oxygen may not be required. That is, in the method of manufacturing a display device of an embodiment, manufacturing costs may be reduced and manufacture efficiency may be improved.

However, the embodiment of the invention is not limited thereto, the final adhesive member AP may be formed by partially performing the polymerization reaction of the resin composition RC in the preliminary adhesive member P-AP state, and then further reacting an unreacted resin composition RC with the ultraviolet light UV after the preliminary adhesive member P-AP is covered with the window WP in another embodiment.

In some embodiments, unlike the configuration illustrated in FIG. 4B, the resin composition RC may be coated on the display module DM to a predetermined thickness to form the preliminary adhesive member P-AP, and after the window WP may be provided on the preliminary adhesive member P-AP, and the ultraviolet light UV for curing the resin composition RC may be provided. In this case, the ultraviolet light UV may be provided through the window WP. In an embodiment, for example, the amount of the ultraviolet light UV irradiated to the preliminary adhesive member P-AP may be an amount of light that completely cures the resin composition RC. In an embodiment, for example, the resin composition RC may be cured by the irradiation of the ultraviolet light UV in a wavelength region of about 365 nm at about 1,000 millijoules per square centimeters (mJ/cm²), but the embodiment of the invention is not limited thereto.

According to the present invention, the adhesive member AP may be formed after the curing with the ultraviolet light UV. The adhesive member AP prepared by the operations described with reference to FIGS. 4A and 4B may be applied to the above-described display device DD, and the adhesive member AP of an embodiment may exhibit excellent adhesion at room temperature and a high temperature.

Referring to FIG. 4C, the method of manufacturing a display device of an embodiment may include disposing and bonding the window WP on the adhesive member AP. In an embodiment, one surface of the adhesive member AP may be attached on the display module DM, and then the window WP may be sequentially attached on the other surface of the adhesive member AP which faces one surface of the adhesive member AP attached to the display module DM. In an embodiment, for example, according to the method of manufacturing a display device of an embodiment, after the window WP is provided on the adhesive member AP, the window WP may be bonded to the adhesive member AP by using a lamination method under normal pressure.

In addition, unlike the one above, the adhesive member AP may be provided to the display device DD by attaching one surface of the adhesive member AP on one surface of the window WP to face the display module DM, and then attaching, to the display module DM, the other surface of the adhesive member AP which faces one surface of the adhesive member AP attached to the window WP.

The display device DD of an embodiment manufactured through the operations described with reference to FIGS. 4A to 4C may include the adhesive member AP including the polymer derived from the above-described resin composition of an embodiment, and may maintain the adhesive state between the window WP and the display module DM by using the adhesive member AP without delamination.

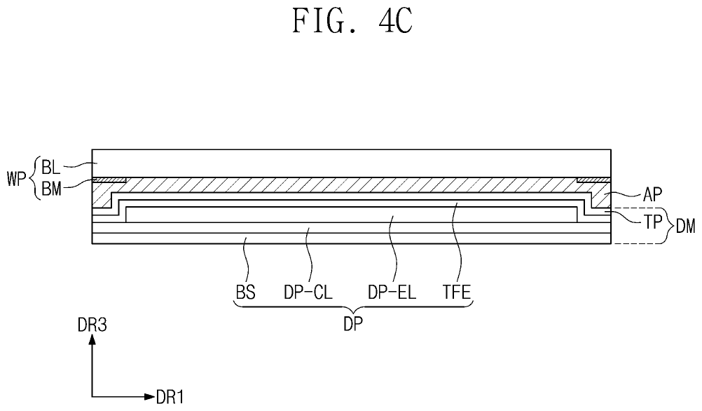

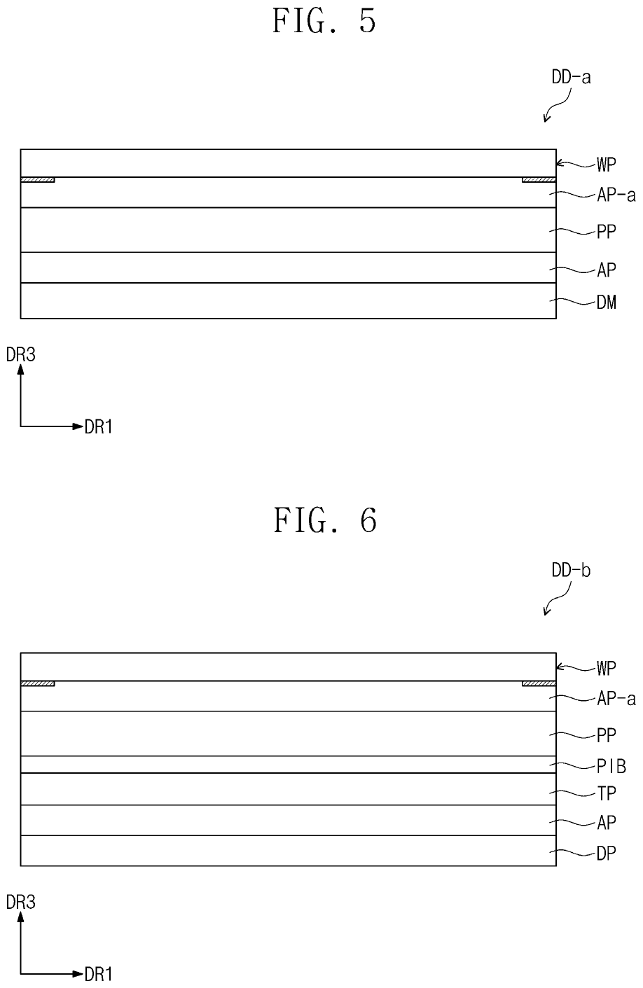

FIG. 5 is a cross-sectional view illustrating a display device according to an embodiment. Hereinafter, in describing the display device illustrated in FIG. 6, the duplicated features which have been described with reference to FIGS. 1 to 4C are not described again, but their differences will be mainly described.

The display device DD-a illustrated in FIG. 5 may further include a light control layer PP and an optical adhesive layer AP-a as compared with the display device DD described with reference to FIGS. 2 and 3. The display device DD-a of an embodiment may further include the light control layer PP disposed between the adhesive member AP and the window WP, and the optical adhesive layer AP-a disposed between the light control layer PP and the window WP.

The light control layer PP may be disposed on a display panel DP to control reflected light in the display panel DP due to external light. The light control layer PP may include, for example, a polarization plate or a color filter layer.

The optical adhesive layer AP-a may be an optically clear adhesive resin layer (OCR). In addition, the optical adhesive layer AP-a may be an optically clear adhesive layer (“OCA”). The optical adhesive layer AP-a may be formed from the above-described resin composition according to an embodiment. The optical adhesive layer AP-a formed from the resin composition of an embodiment may have a 180° peel strength of about 400 gf/25 mm or more at room temperature, and may have a 180° peel strength of about 100 gf/25 mm or more at a high temperature. The display device DD-a including the optical adhesive layer AP-a may exhibit excellent reliability. The optical adhesive layer AP-a of an embodiment may exhibit high adhesion. The display device DD-a of an embodiment includes the optical adhesive layer AP-a and the adhesive member AP formed from the resin composition of an embodiment. The optical adhesive layer AP-a and the adhesive member AP have high adhesion, and thus the display device DD-a may exhibit excellent reliability characteristics since the delamination phenomenon does not occur at the interface between the optical adhesive layer AP-a and the adhesive member AP at room temperature and a high temperature.

FIG. 6 is a cross-sectional view illustrating a display device according to an embodiment. Hereinafter, in describing the display device of an embodiment illustrated in FIG. 6, the duplicated features which have been described with reference to FIGS. 1 to 5 are not described again, but their differences will be mainly described.

The display device DD-b of an embodiment illustrated in FIG. 6 may further include a light control layer PP, an optical adhesive layer AP-a, and an interlayer adhesive layer PIB as compared with the display device DD described with reference to FIGS. 2 and 3. The display device DD-b of an embodiment illustrated in FIG. 6 may further include the light control layer PP disposed between an adhesive member AP and a window WP, and the optical adhesive layer AP-a disposed between the light control layer PP and the window WP like the display device DD-a of an embodiment illustrated in FIG. 5.

In the display device DD-b of an embodiment, the adhesive member AP may be provided between a display panel DP and an input sensing unit TP. That is, the input sensing unit TP may not be disposed directly on the display panel DP, and the display panel DP and the input sensing unit TP may be coupled to each other via the adhesive member AP. In an embodiment, for example, the adhesive member AP and may be disposed between the encapsulation layer TFE (see FIG. 3) of the display panel DP and the input sensing unit TP.

The interlayer adhesive layer PIB may be provided to the bottom side of the light control layer PP. The interlayer adhesive layer PIB may be disposed between the input sensing unit TP and the light control layer PP, and be formed of an adhesive material having superior anti-moisture permeability. In an embodiment, for example, the interlayer adhesive layer PIB may include polyisobutylene. The interlayer adhesive layer PIB may be disposed on the input sensing unit TP to prevent corrosion of sensing electrodes of the input sensing unit TP. The display device DD-b of an embodiment includes the optical adhesive layer AP-a and the adhesive member AP formed from the resin composition RC according to an embodiment. Accordingly, the display device DD-b of an embodiment may exhibit excellent reliability.

Hereinafter, with reference to Examples and Comparative Examples, an adhesive member and a display device formed from a resin composition according to an embodiment of the invention will be described in detail. In addition, Examples described below are only illustrations to assist the understanding of the invention, and the scope of the invention is not limited thereto.

### EXAMPLES

### 1. Synthesis of (Meth)Acrylate Copolymer

In Synthetic Examples 1 to 7 below, the molecular weight measurement was performed using a Gel Permeation Chromatography (“GPC”) analysis device, HLC-8420GPC, manufactured by TOSOH Corporation. In this case, from a size exclusion chromatography (“SEC”) curve obtained by using TSKgel SUPER HZM-N as a measurement column and a refractive index (“RI”) detector, the weight-average molecular weight (Mw) value obtained with a standard polystyrene (“PS”) conversion was selected.

Each composition ratio of the (meth)acrylate copolymer was calculated from the integral ratio of the signal belonging to each monomer component in the proton nuclear magnetic resonance (“NMR”) spectrum in the measurement with an NMR analyzer, AVANCE III 300M, manufactured by BRUKER. Also, deuterated chloroform (manufactured by KANTO CHEMICAL CO., INC.) was used as a deuterated solvent during the measurement.

### 1) Synthetic Example 1: Synthesis of MC-1

Butyl acetate (40 mL) was added to a round-bottom flask equipped with a cooling tube, a drip funnel, a nitrogen introduction tube, and a magnetic stirrer and was stirred at room temperature for about 30 minutes while nitrogen bubbling to perform the deoxidation of the solvent. This was heated in an oil bath until the internal temperature reached about 90° C., and then, 14.10 g of methyl methacrylate (MMA, manufactured by Tokyo Chemical Industry Co., Ltd.), 11.10 g of isobornyl methacrylate (IBXMA, manufactured by Tokyo Chemical Industry Co., Ltd.), and 1.47 g of 2-hydroxyethyl methacrylate (HEMA, manufactured by Tokyo Chemical Industry Co., Ltd.) as methacrylic acid monomers, 2.21 g of V-601 (manufactured by FUJIFILM Wako Pure Chemical Corporation) as a thermal polymerization initiator, and 10 mL of butyl acetate were made into a homogeneous solution in advance and added to the drip funnel, and the homogeneous solution in the drip funnel was slowly dropped into the flask for about 1 hour by opening the cock. Thereafter, the resulting mixture was stirred for about 1 hour to perform a polymerization reaction. After the polymerization reaction, the internal temperature was cooled to about 40° C., and after the temperature was stabilized, 1.50 mg of dibutyltin dilaurate (manufactured by FUJIFILM Wako Pure Chemical Corporation) was added as a catalyst and 0.10 g of 2-isocyanatoehtyl acrylate was added as an isocyanate to perform the reaction for about 1 hour. Next, 800 mL of ethanol was added to the 1000-mL beaker and stirred with the magnetic stirrer, and the solution after the polymerization reaction in the flask was dropped thereto in small portions to precipitate. The precipitate was filtered through a suction filtration, and was washed again with ethanol to remove butyl acetate and unreacted monomers. The precipitate was dried under reduced pressure to obtain 20.0 g of white powder (MC-1), which is a copolymer of MMA, IBXMA, and acryl group-modified HEMA. The weight-average molecular weight of the white powder (MC-1) was about 10,300, and the molecular weight distribution was about 1.47. The weight composition ratio of the copolymer was MMA:IBXMA:(acryl group-modified HEMA)=70.3:23.8:5.9.

### 2) Synthetic Example 2: Synthesis of MC-2

White powder (MC-2, 18.0 g), which is a copolymer of MMA, IBXMA, and acryl group-modified HEMA, was synthesized in the same manner as in Synthetic Example 1, except for performing the copolymerization of MMA, IBXMA, and HEMA by using 3.33 g of V-601, a thermal polymerization initiator, and then using 0.60 g of 2-isocyanatoethyl acrylate. The weight-average molecular weight of the white powder (MC-2) was about 6,500, and the molecular weight distribution was about 1.37. The weight composition ratio of the copolymer was MMA:IBXMA:(acryl group-modified HEMA)=68.6:25.3:6.1.

### 3) Synthetic Example 3: Synthesis of MC-3

White powder (MC-3, 19.2 g), which is a copolymer of MMA, IBXMA, and acryl group-modified HEMA, was synthesized in the same manner as in Synthetic Example 1, except for performing the copolymerization of MMA, IBXMA, and HEMA by using 1.10 g of V-601, a thermal polymerization initiator, and then using 0.05 g of 2-isocyanatoethyl acrylate. The weight-average molecular weight of the white powder (MC-3) was about 24,000, and the molecular weight distribution was about 1.35. The weight composition ratio of the copolymer was MMA:IBXMA:(acryl group-modified HEMA)=69.6:25.2:5.2.

### 4) Synthetic Example 4: Synthesis of MC-4

White powder (MC-4, 22.1 g), which is a copolymer of MMA, IBXMA, and HEMA, was synthesized in the same manner as in Synthetic Example 1, except that dibutyltin dilaurate and 2-isocyanatoethy acrylate were not added. The weight-average molecular weight of the white powder (MC-4) was about 9,700, and the molecular weight distribution was about 1.38. The weight composition ratio of the copolymer was MMA:IBXMA:HEMA=68.9:25.4:5.7.

### 5) Synthetic Example 5: Synthesis of MC-5

The synthesis was performed in the same manner as in Synthetic Example 1 except that IBXMA and HEMA were not added and 25.2 g of MMA was used and 2.21 g of V-601 was used, thereby obtaining white powder (MC-5, 18.3 g) which is an MMA homopolymer. The weight-average molecular weight of the white powder (MC-5) was about 6,100, and the molecular weight distribution was about 1.56. 6) Synthetic Example 6: Synthesis of MC-6

The synthesis was performed in the same manner as in Synthetic Example 1 except that MMA and HEMA were not added and 25.1 g of IBXMA was used and 5.77 g of V-601 was used, thereby obtaining white powder (MC-6, 8.80 g) which is a IBXMA homopolymer. The weight-average molecular weight of the white powder (MC-6) was about 4,300, and the molecular weight distribution was about 1.26.

### 7) Synthetic Example 7: Synthesis of MC-7

The synthesis was performed in the same manner as in Synthetic Example 1 except that MMA and IBXMA were not added and 17.5 g of HEMA was used and 4.42 g of V-601 was used, thereby obtaining white powder (MC-7, 15.1 g) which is a HEMA homopolymer. The weight-average molecular weight of the white powder (MC-7) was about 4,800, and the molecular weight distribution was about 1.62.

### 2. Preparation of Resin Composition

Each of components listed in Tables 1 and 2 was mixed to prepare resin compositions of Examples and Comparative Examples. Each of components was provided to a light-shielding airtight container according to the mixing ratio listed in Tables 1 and 2. Thereafter, the resulting mixture was stirred at room temperature for about 12 hours by using the mix rotor to prepare the resin compositions of Examples and Comparative Examples (unit: parts by weight).

TABLE 1

| | | Glass | | | | | | | |
|---|---|---|---|---|---|---|---|---|---|
| | | transition | | | | | | | |
| | | temperature | molecular | | | | Comparative | Comparative | Comparative |
| Component | Type | (Tg, ° C.) | weight | Example 1 | Example 2 | Example 3 | Example 1 | Example 2 | Example 3 |
| (Meth)acrylate | MC-1 | 112 | 10,300 | 10 | | | | | |
| copolymer | MC-2 | 106 | 6,500 | | 10 | | | | |
| | MC-3 | 114 | 24,000 | | | 10 | | | |
| | MC-4 | 122 | 9,700 | | | | | 10 | |
| | MC-5 | 99 | 6,100 | | | | | | 10 |
| | MC-6 | 151 | 4,300 | | | | | | |
| | MC-7 | 123 | 4,800 | | | | | | |
| Urethane | UF-C051 | | 32,000 | 5 | 5 | 5 | 5 | 5 | 5 |
| (meth)acrylate | UN-6304 | | 13,000 | 5 | 5 | 5 | 5 | 5 | 5 |
| oligomer | | | | | | | | | |
| Monofunctional | 4HBA | | | 5 | 5 | 5 | 5 | 5 | 5 |
| (meth)acrylate | 2EHA | | | 85 | 85 | 85 | 85 | 85 | 85 |
| monomer | | | | | | | | | |
| Photoinitiator | Omnirad 819 | | | 3 | 3 | 3 | 3 | 3 | 3 |

TABLE 2

| | | Glass | | | |
|---|---|---|---|---|---|
| | | transition | | | |
| | | temperature | molecular | Comparative | Comparative |
| Component | Type | (Tg, ° C.) | weight | Example 4 | Example 5 |
| (Meth)acrylate | MC-1 | 112 | 10,300 | | |
| copolymer | MC-2 | 106 | 6,500 | | |
| | MC-3 | 114 | 24,000 | | |
| | MC-4 | 122 | 9,700 | | |
| | MC-5 | 99 | 6,100 | | |
| | MC-6 | 151 | 4,300 | 10 | |
| | MC-7 | 123 | 4,800 | | 10 |
| Urethane | UF-C051 | | 32,000 | 5 | 5 |
| (meth)acrylate | UN-6304 | | 13,000 | 5 | 5 |
| oligomer | | | | | |
| Monofunctional | 4HBA | | | 5 | 5 |
| (meth)acrylate | 2EHA | | | 85 | 85 |
| monomer | | | | | |
| Photoinitiator | Omnirad 819 | | | 3 | 3 |

### <Materials in Tables 1 and 2>

MC-1: Copolymer of MMA, IBXMA, and acryl group-modified HEMA in Synthetic Example 1
MC-2: Copolymer of MMA, IBXMA, and acryl group-modified HEMA in Synthetic Example 2
MC-3: Copolymer of MMA, IBXMA, and acryl group-modified HEMA in Synthetic Example 3
MC-4: Copolymer of MMA and IBXMA in Synthetic Example 4
MC-5: MMA homopolymer in Synthetic Example 5
MC-6: IBXMA homopolymer in Synthetic Example 6
MC-7: HEMA homopolymer in Synthetic Example 7
UF-C051: Urethane acrylate oligomer (weight-average molecular weight of 32,000) (manufactured by Kyoeisha Chemical Co., Ltd.)
UN-6304: Urethane acrylate oligomer (weight-average molecular weight of 13,000) (manufactured by Negami Chemical Industrial Co., Ltd.)
2EHA: 2-Ethylhexyl acrylate (manufactured by TOAGOSEI Co., Ltd.)
4HBA: 4-Hydroxy butyl acrylate (manufactured by Osaka Organic Chemical Industry Ltd.)
Omnirad 819: Phenyl bis(2,4,6-trimethylbenzoyl)phosphine oxide (manufactured by IGM Resins, Inc.)

### 2. Evaluation of Resin Composition and Adhesive Member

The uniformity of the resin compositions of Examples and Comparative Examples, and the 180° peel strengths at 25° C. and 60° C. were evaluated and the results are shown in Table 3 below.

### <Uniformity of Resin Composition and Cured Product>

The uniformity of the prepared Example and Comparative Example compositions was confirmed with naked eyes, and the uniformity of the cured product after light irradiation of the prepared Example and Comparative Example compositions was confirmed with naked eyes, and evaluated according to the following evaluation criteria.
o: Both the resin composition and the cured product after light irradiation are uniform
Δ: The resin composition is uniform, but the cured product after light irradiation is non-uniform (generation of insoluble matter/white turbidity, etc.)
x: Both the resin composition and the cured product after light irradiation are non-uniform (generation of insoluble matter/white turbidity, etc.)

### <1800 Peel Strength of Adhesive Member>

The prepared resin composition was applied onto a slide glass substrate having a size of about 76 millimeters (mm)×26 mm to have a thickness of about 50 km. The applied resin composition was irradiated with the ultraviolet light so as to have a total amount of light of about 1,000 mJ/cm² by using the UV-LED lamp having a peak at about 365 nm, thereby forming an adhesive member. Here, a PET film substrate having a size of about 150 mm×20 mm and a thickness of about 50 m was bonded with an atmospheric pressure laminator, and the PET film substrate was pressed and defoamed in an autoclave under conditions of 30° C. and 0.5 megapascals (MPa) for 5 minutes to prepare a specimen for measuring peel strength.

According to JIS K6854, a 180° peel strength test was performed in temperature conditions of about 25° C. and about 60° C. The average value of the peel strength within the range of about 20 mm to about 80 mm from the start of peeling was selected as the evaluation value.

TABLE 3

| | | | | Comparative | Comparative | Comparative | Comparative | Comparative |
|---|---|---|---|---|---|---|---|---|
| Division | Example 1 | Example 2 | Example 3 | Example 1 | Example 2 | Example 3 | Example 4 | Example 5 |
| Uniformity | ◯ | ◯ | ◯ | ◯ | ◯ | ◯ | Δ | X |
| Adhesiveness: | 1264 | 1090 | 1150 | 50 | 960 | 240 | 80 | — |
| 25° C. peel | | | | | | | | |
| strength | | | | | | | | |
| [gf/25 mm] | | | | | | | | |
| Adhesiveness: | 233 | 114 | 194 | 20 | 30 | 20 | 20 | — |
| 60° C. peel | | | | | | | | |
| strength | | | | | | | | |
| [gf/25 mm] | | | | | | | | |

Referring to Table 3, it may be seen that the resin compositions of Examples 1 to 3 including the (meth)acrylate copolymer (hereinafter, referred to as a copolymer) of an embodiment synthesized in Synthetic Examples 1 to 3 exhibited excellent adhesiveness at both room temperature (about 25° C.) and a high temperature (about 60° C.) from the measurement results of the specimen for measuring peel strength, the specimen being prepared by light irradiation once in the atmosphere including oxygen. This result is considered to be due to the formation of a cross-linking structure with the resin composition by including the copolymer having a (meth)acroyl group in the side chain substituent in the resin composition of an example, thus segregating the copolymer of an embodiment to the outermost side of the adhesive member when the resin composition is cured, thereby ensuring adhesiveness by constant cohesive force, and allowing the (meth)acryloyl group of the side chain substituent to undergo a polymerization reaction late.

On the other hand, Comparative Example 1 showed a result of significantly deteriorating adhesiveness at room temperature as well as at a high temperature by using the resin composition which does not include the copolymer according to the invention. This result is because the curing inhibition phenomenon occurred on the outermost surface of the adhesive member due to the influence of oxygen in the atmosphere.

Comparative Example 2 is a resin composition including a copolymer (MMA/IBXMA/HEMA) having no (meth)acryloyl group in the side chain substituent, and exhibits adhesiveness at room temperature similar to those of Examples according to the invention, but at a high temperature (about 60° C.), the adhesiveness was significantly deteriorated compared to Examples. This result is considered to be due to the fact that, at about room temperature, constant adhesiveness may be ensured for the same reason as the copolymer according to the invention, but since crosslinking with the resin composition does not occur, fluidity is extremely high at a high temperature, and cohesive force of the whole is lost.

In Comparative Examples 3 to 5, each of the resin compositions comprises a homopolymer of a monomer. As shown in Comparative Example 3, when the resin composition includes the MMA homopolymer, it may be confirmed that compatibility was excellent but peel strength was not expressed. As shown in Comparative Example 4, when the resin composition includes the IBXMA homopolymer, the resin composition showed a result of being segregated after curing, and thus, the significant deterioration of the peel strength at both room temperature and a high temperature. As shown in Comparative Example 5, when the resin composition includes the HEMA homopolymer, the resin composition showed a result that the adhesiveness was significantly deteriorated so that the peel strength was not measured at room temperature and at a high temperature, and the compatibility of the resin composition was insufficient.

The resin composition of an embodiment may provide properties which may inhibit the phenomenon in which the surface curing is deteriorated due to oxygen in the air during photo-curing. Accordingly, the adhesive member formed from the resin composition of an embodiment may exhibit excellent adhesiveness not only at room temperature but also at a high temperature.

The adhesive member of an embodiment has excellent peel strength, and thus the display device including the same may exhibit excellent adhesive reliability.

In addition, according to the method of manufacturing a display device of an embodiment, the adhesive member may be prepared through a single light irradiation in the atmosphere, and thus an additional increase in process and equipment is not required, so that production efficiency may be improved and manufacturing costs may be reduced.

Although the invention has been described with reference to a preferred embodiment of the invention, it will be understood that the invention should not be limited to these preferred embodiments but various changes and modifications can be made by those skilled in the art without departing from the spirit and scope of the invention.

Accordingly, the technical scope of the invention is not intended to be limited to the contents set forth in the detailed description of the specification, but is intended to be defined by the appended claims.

What is claimed is:

1. A resin composition comprising:
a (meth)acrylate copolymer comprising a first structural unit represented by following Formula 1a, a second structural unit represented by following Formula 1b, and a third structural unit represented by following Formula 1c;
a urethane (meth)acrylate oligomer;
a monofunctional (meth)acrylate monomer; and
a photoinitiator: 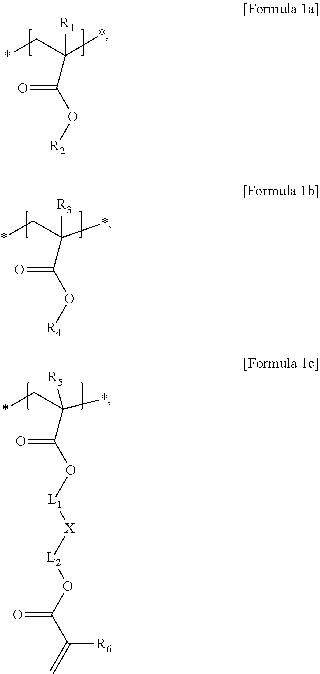
wherein, in Formula 1a to Formula 1c above,
R₁, R₃, R₅, and R₆ are each independently a hydrogen atom or a methyl group,
R₂ is a substituted or unsubstituted alkyl group having 1 to 18 carbon atoms, or an oxy group,
R₄ is a functional group having at least one substituted or unsubstituted aliphatic ring group,
L₁ and L₂ are each independently a substituted or unsubstituted alkylene group having 1 to 18 carbon atoms, or a substituted or unsubstituted alkyleneoxy group having 1 to 18 carbon atoms, and
X is an ether group, an ester group, a urethane group, or an amide group.

2. The resin composition of claim 1, wherein the (meth)acrylate copolymer has a weight-average molecular weight of about 1,000 grams per mol (g/mol) to about 50,000 g/mol.

3. The resin composition of claim 1, wherein, with respect to 100 parts by weight of the urethane (meth)acrylate oligomer, the monofunctional (meth)acrylate monomer, and the photoinitiator, the (meth)acrylate copolymer is included in an amount of about 0.1 parts by weight to about 50 parts by weight.

4. The resin composition of claim 1, wherein, with respect to 100 mole percents (mol %) of the (meth)acrylate copolymer, a content of the third structural unit is about 0.01 mol % to about 50 mol %.

5. The resin composition of claim 1, wherein the urethane (meth)acrylate oligomer has a weight-average molecular weight of about 5,000 to about 100,000.

6. The resin composition of claim 1, wherein the resin composition has a peel strength of about 400 gf/25 mm or more at about 25° C. according to Japanese Industrial Standard (JIS) K6854 after photo-cured.

7. The resin composition of claim 1, wherein the resin composition has a peel strength of about 100 gf/25 mm or more at about 60° C. according to JIS K6854 after photo-cured.

8. The resin composition of claim 1, wherein the resin composition does not comprise an organic solvent.

9. The resin composition of claim 1, wherein the (meth)acrylate copolymer is a random copolymer, and represented by following Formula 1 below: 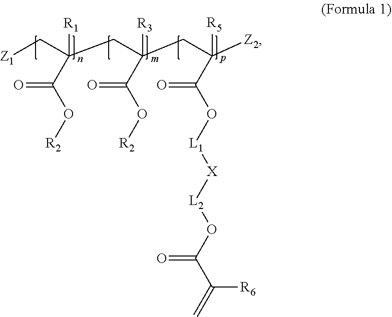
wherein, in Formula 1 above,
Z₁ and Z₂ are each independently a functional group which does not have activity of radicals, cations, and anions,
0.01≤p/(n+m+p)≤50, and
R₁ to R₆, L₁, L₂ and X are the same as defined in Formula 1a to Formula 1c above.

10. A method of manufacturing a display device comprising:
providing, on a first substrate, a resin composition comprising a (meth)acrylate copolymer, a urethane (meth)acrylate oligomer, a monofunctional (meth)acrylate monomer, and a photoinitiator;
irradiating the resin composition with ultraviolet light in an atmosphere to form an adhesive member; and
providing a second substrate on the adhesive member,
wherein the (meth)acrylate copolymer comprises a first structural unit represented by following Formula 1a, a second structural unit represented by following Formula 1b, and a third structural unit represented by following Formula 1c: 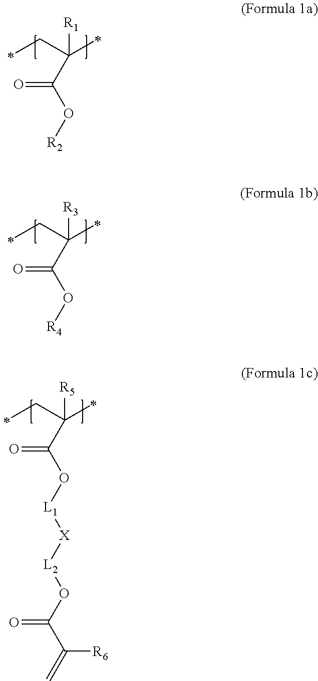
wherein, in Formula 1a to Formula 1c above,
R₁, R₃, R₅, and R₆ are each independently a hydrogen atom or a methyl group,
R₂ is a substituted or unsubstituted alkyl group having 1 to 18 carbon atoms, or an oxy group,
R₄ is a functional group having at least one substituted or unsubstituted aliphatic ring group,
L₁ and L₂ are each independently a substituted or unsubstituted alkylene group having 1 to 18 carbon atoms, or a substituted or unsubstituted alkyleneoxy group having 1 to 18 carbon atoms, and
X is an ether group, an ester group, a urethane group, or an amide group.

11. The method of claim 10, wherein the (meth)acrylate copolymer has a weight-average molecular weight of about 1,000 g/mol to about 50,000 g/mol.

12. The method of claim 10, wherein the adhesive member has a peel strength of about 400 gf/25 mm or more at about 25° C. according to JIS K6854.

13. The method of claim 10, wherein the resin composition does not comprise an organic solvent.

14. A display device comprising:
a display panel;
a window disposed on the display panel; and
an adhesive member which is disposed between the display panel and the window, and comprises a polymer derived from a resin composition comprising a (meth)acrylate copolymer, a urethane (meth)acrylate oligomer, a monofunctional (meth)acrylate monomer, and a photoinitiator,
wherein the (meth)acrylate copolymer comprises a first structural unit represented by following Formula 1a, a second structural unit represented by following Formula 1b, and a third structural unit represented by following Formula 1c: 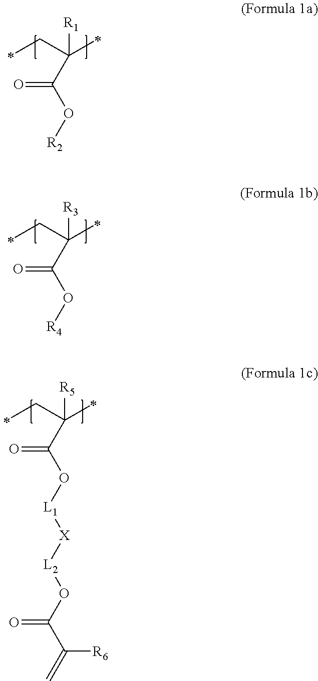
wherein, in Formula 1a to Formula 1c above,
R₁, R₃, R₅, and R₆ are each independently a hydrogen atom or a methyl group,
R₂ is a substituted or unsubstituted alkyl group having 1 to 18 carbon atoms, or an oxy group,
R₄ is a functional group having at least one substituted or unsubstituted aliphatic ring group,
L₁ and L₂ are each independently a substituted or unsubstituted alkylene group having 1 to 18 carbon atoms, or a substituted or unsubstituted alkyleneoxy group having 1 to 18 carbon atoms, and
X is an ether group, an ester group, a urethane group, or an amide group.

15. The display device of claim 14, wherein, with respect to 100 parts by weight of the urethane (meth)acrylate oligomer, the monofunctional (meth)acrylate monomer, and the photoinitiator, the (meth)acrylate copolymer is included in an amount of about 0.1 parts by weight to about 50 parts by weight.

16. The display device of claim 14, wherein, with respect to 100 mol % of the (meth)acrylate copolymer, the content of the first structural unit is about 0.01 mol % to about 50 mol %.

17. The display device of claim 14, further comprising a light control layer disposed between the adhesive member and the window and an optical adhesive layer disposed between the light control layer and the window,
wherein the optical adhesive layer comprises the polymer derived from the resin composition.

18. The display device of claim 14, wherein the (meth)acrylate copolymer has a glass transition temperature of about 100° C. or higher.

19. The display device of claim 14, wherein the adhesive member has a peel strength of about 400 gf/25 mm or more at about 25° C. and about 100 gf/25 mm or more at about 60° C. according to JIS K6854.

20. The display device of claim 14, wherein the adhesive member has a thickness of about 50 micrometers (μm) to about 200 μm.
